(19) United States
(12) Patent Application Publication
(10) Pub. No.: US 2025/0331219 A1
(43) Pub. Date: Oct. 23, 2025

(54) EDMOS FET with Variable Drift Region Resistance

(71) Applicant: pSemi Corporation, San Diego, CA (US)

(72) Inventor: Jagar Singh, New York, NY (US)

(21) Appl. No.: 18/639,640

(22) Filed: Apr. 18, 2024

(51) Int. Cl. H01L 29/78; H01L 29/06; H01L 29/08; H01L 29/10; H01L 29/423

(52) U.S. Cl. CPC H10D 30/611; H10D 30/657; H10D 62/106; H10D 62/156; H10D 62/393; H10D 64/512

(57) ABSTRACT

MOSFET-based IC architectures that mitigate or eliminate the relatively high resistance of extended drift regions in EDMOS and LDMOS devices, resulting in MOSFETs that are reliable, capable of handling relatively high drain voltages, and provide high currents at relatively low drain voltages. Embodiments encompass EDMOS or LDMOS devices that include a secondary transistor comprising a differently-doped well located adjacent at least one drift region and between the drain and the body of the device, with a variably-biased secondary gate structure aligned over the differently doped well. Biasing the secondary gate structure to an OFF state causes the differently-doped well to exhibit high resistance, resulting in a high breakdown voltage for the device. Biasing the secondary gate structure to an ON state causes the differently-doped well to exhibit low resistance, resulting in a reduced drain resistance path that improves the linearity and the error-vector magnitude characteristics of the device.

### BACKGROUND

### (1) Technical Field

This invention relates to electronic integrated circuits, and more particularly to electronic integrated circuits having metal-oxide-semiconductor field-effect transistors (MOSFETs).

### (2) Background

Virtually all modern electronic products—including laptop computers, mobile telephones, and electric cars—utilize MOSFET-based integrated circuits (ICs). A number of architectural variations exist for MOSFETs. For example, N− type Extended Drain MOS (NEDMOS) FETs fabricated using silicon-on-insulator (SOI) processes and Laterally-Diffused MOS (LDMOS) FETs fabricated using bulk silicon are common transistor devices capable of handling relatively high drain voltages. For example, FIG. 1A is a stylized cross-sectional view of a typical prior art SOI IC structure for a single NEDMOS FET 100. The SOI structure includes a substrate 102, a buried-oxide (BOX) insulator layer 104, and an active layer 106 (note that the dimensions for the elements of the SOI IC structure are not to scale; some dimensions have been exaggerated for clarity or emphasis). The substrate 102 is typically a semiconductor material such as silicon, but other materials may be used. The BOX layer 104 is a dielectric, and is often SiO2 formed as a “top” surface of the silicon substrate 102.

The active layer 106 may include some combination of implants and/or layers that include dopants, dielectrics, polysilicon, conductors, passivation, and other materials to form active and/or passive electronic components and/or mechanical structures. For example, the NEDMOS FET 100 of FIG. 1A includes an N+ source S, a P− body region B, a gate structure G, an N− drift region, and an N+ drain D. The designation “N− means a lesser concentration of N− type dopant (e.g., arsenic or phosphorous) than the designation “N+”. A conductive source contact 112, a conductive gate contact 114, and a conductive drain contact 116, which may be self-aligned silicides (also known as “salicides”), are respectively formed in contact with the source S, the gate structure G, and the drain D. The salicides may be, for example, NiSi. Stylized electrical terminals Source, Gate, and Drain are shown coupled to the corresponding source contact 112, gate contact 114, and drain contact 116.

The illustrated gate structure G includes a conductive layer 108, such as N+doped polysilicon, atop an insulating gate oxide (GOX) layer 110. In the illustrated example, the gate structure G is surrounded by insulating spacers 118. Parts of the gate structure G, the N− drift region, and the drain D are coated with a dielectric 120, such as SiO₂, Si₃N₄, etc., which in turn is overlaid with a salicide block (SAB) layer 122, such as silicon nitride (SiN). In some embodiments, a lightly-doped drain (LDD) region 124 may be formed underneath the spacer 118 adjacent the source S. In some embodiments, a doped halo region 126 may be formed between at least portions of the source S and body B.

The BOX layer 104 and the active layer 106 (which may include multiple FETs) may be collectively referred to as a “device region” or “substructure” 130 for convenience (noting that other structures or regions may intrude into the substructure 130 in particular IC designs). A superstructure 132 of various elements, regions, and structures may be fabricated on or above the substructure 130 in order to implement particular functionality. The superstructure 132 may include, for example, conductive interconnections from the illustrated FET 100 to other components (including other FETs) and/or external contacts, passivation layers, and protective coatings.

FIG. 1B is a top plan view of the prior art SOI IC structure of FIG. 1A. The cross-section shown in FIG. 1A is along line X-X of FIG. 1B. The source S, the gate structure G, and the drain D overlay a field of N+ material 140 in this example. The drift region between the gate structure G and the drain D is shown within a dotted outline 141. The illustrated example shows that the source S is associated with multiple source contacts 112 and the drain D is associated with multiple drain contacts 116, while the gate structure G in this particular example is shown as having a single gate contact 114. Also shown in FIG. 1B is the top side of a body contact region 142 having an associated conductive body contact 144. In the illustrated example, the body contact region 142 comprises a P+ region formed in electrical contact with the P− body B to provide a fourth terminal to the FET 100.

A bulk semiconductor IC LDMOS structure has an architecture similar to the example NEDMOS of FIG. 1A but omits the BOX layer 104. There are typically other differences, most notably that the drift region typically surrounds the drain D and generally extends beneath the drain. In addition, any substrate contact may be modified and placed at a different location.

The N− drift region enables NEDMOS and LDMOS FETs to better able to withstand high OFF-state and ON-state drain voltages than conventional MOSFETs and thus improves the reliability of such devices. However, the extended drift region increases the resistance on the drain side of the device, which adversely impacts the knee voltage (the transition boundary between the ohmic or linear region and the approximately constant-current or saturation region) of the transistor and reduces drain current.

The present invention is directed to overcoming the drawbacks of conventional NEDMOS and LDMOS FETs.

### SUMMARY

The present invention encompasses MOSFET-based IC architectures that mitigate or eliminate the problems caused by the relatively high resistance of extended drift regions in EDMOS and LDMOS devices, resulting in MOSFETs that are reliable, capable of handling relatively high drain voltages, and provide high currents at relatively low drain voltages. Embodiments of the present invention encompass EDMOS or LDMOS devices that include a secondary transistor comprising a differently-doped well located adjacent at least one extended drift region and between the drain and the body of the device, with a variably-biased secondary gate structure G_{DR} atop a second insulating gate oxide layer aligned over the differently-doped well.

Setting the bias to the secondary gate structure G_{DR} to be no more than the threshold voltage V_{TH} of the device causes the differently-doped well to exhibit high resistance, resulting in a high breakdown voltage BV_{DSS} for the device and limiting high drain voltages from reaching the junction between the device body and the extended drift region. Setting the bias to the secondary gate structure G_{DR} to be greater than the threshold voltage V_{TH} of the device causes the differently-doped well to exhibit low resistance, resulting in a reduced resistance path through the extended drift region between the drain D and the device body. The reduced resistance path increases the device drain current Id compared to a conventional EDMOS or LDMOS device. The reduced resistance path also improves the linearity and the error-vector magnitude (EVM) characteristics of the device.

The details of one or more embodiments of the invention are set forth in the accompanying drawings and the description below. Other features, objects, and advantages of the invention should be apparent from the description and drawings, and from the claims.

### DESCRIPTION OF THE DRAWINGS

FIG. 1A is a stylized cross-sectional view of a typical prior art SOI IC structure for a single NEDMOS FET.

FIG. 1B is a top plan view of the prior art SOI IC structure of FIG. 1A.

FIG. 2A is a stylized cross-sectional view of a single SOI NEDMOS FET in accordance with the present invention.

FIG. 2B is a stylized top plan view of the IC structure of FIG. 2A, excluding salicide and SAB layers.

FIG. 2C is a stylized cross-sectional view of a single SOI PEDMOS FET in accordance with the present invention.

FIG. 3 is a stylized graph of drain current Id versus drain voltage Vd of two different types of NEDMOS FETs.

FIG. 4 is a process flowchart showing one process for making a NEDMOS device with a secondary gate structure G_{DR} that is suitable for some contemporary IC front-end-of-line (FEOL) foundries.

FIG. 5 is a top plan view of a substrate that may be, for example, a printed circuit board or chip module substrate (e.g., a thin-film tile).

Like reference numbers and designations in the various drawings indicate like elements unless the context requires otherwise.

### DETAILED DESCRIPTION

The present invention encompasses MOSFET-based IC architectures that mitigate or eliminate the problems caused by the relatively high resistance of extended drift regions in EDMOS and LDMOS devices, resulting in MOSFETs that are reliable, capable of handling relatively high drain voltages, and provide high currents at relatively low drain voltages. Embodiments of the present invention encompass EDMOS or LDMOS devices that include a secondary transistor comprising a differently-doped well located adjacent at least one extended drift region and between the drain and the body of the device, with a variably-biased secondary gate structure G_{DR} atop a second insulating gate oxide layer aligned over the differently-doped well.

Setting the bias to the secondary gate structure G_{DR} to be no more than the threshold voltage V_{TH} of the device causes the differently-doped well to exhibit high resistance in OFF-state operation, resulting in a high breakdown voltage BV_{DSS} for the device and limiting high drain voltages from reaching the junction between the device body and the extended drift region. Setting the bias to the secondary gate structure G_{DR} to be greater than the threshold voltage V_{TH} of the device causes the differently-doped well to exhibit low resistance, resulting in a reduced resistance path through the extended drift region between the drain D and the device body. The reduced resistance path increases the device drain current Id compared to a conventional EDMOS or LDMOS device. The reduced resistance path also improves the linearity and the error-vector magnitude (EVM) characteristics of the device.

For purposes of simplicity, the following discussion will focus on N− type EDMOS (NEDMOS) devices. However, the invention may be applied to P− type Extended Drain MOS (PEDMOS) FETs and to N− type and P− type LDMOS FETs.

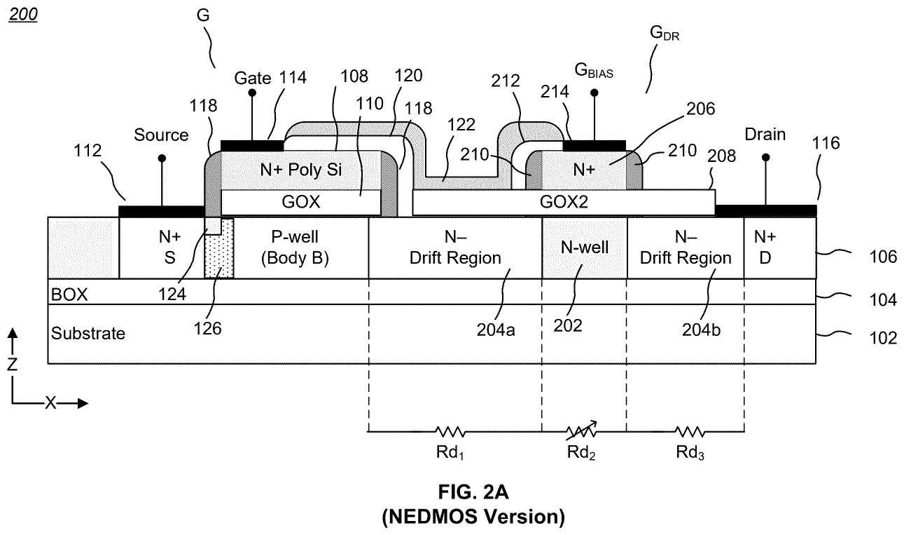

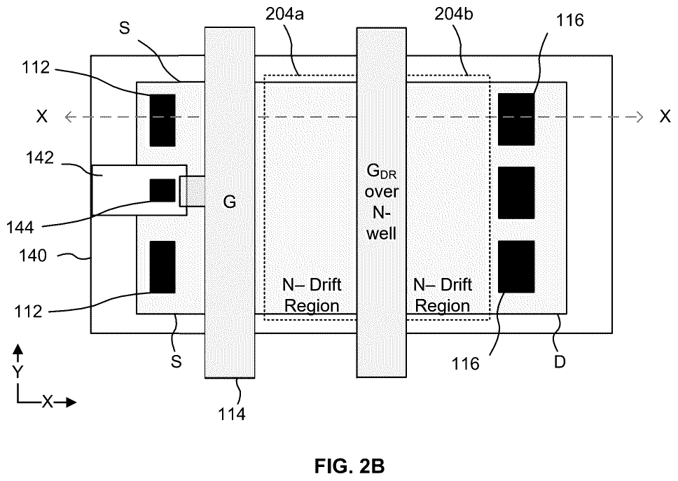

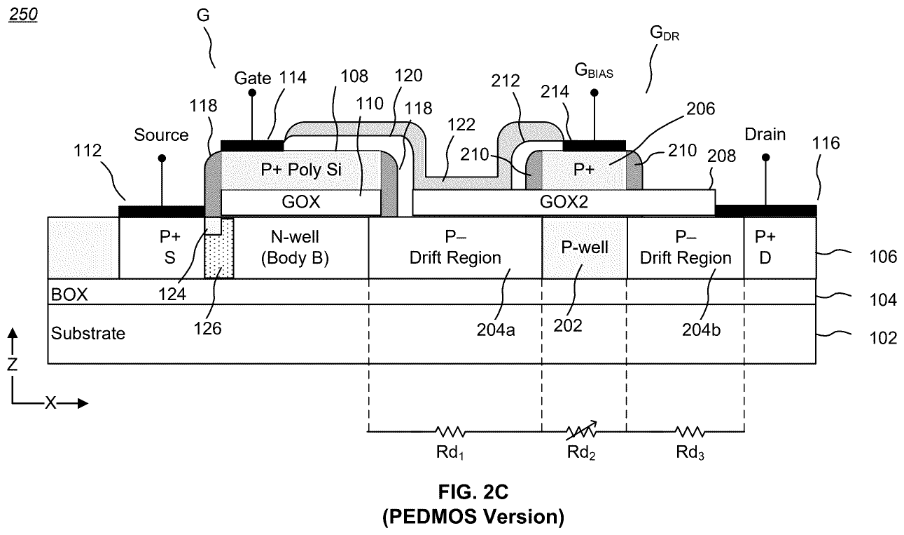

FIG. 2A is a stylized cross-sectional view of a single SOI NEDMOS FET 200 in accordance with the present invention. Similar in many respects to the NEDMOS FET 100 described above, the illustrated NEDMOS FET 200 differs by including a secondary gate structure G_{DR} overlying a lightly-doped N-well region 202 adjacent at least one of a first or second N− drift region 204a, 204b and between the N+ drain D and the P− type body B of the device. In the illustrated example, the N-well region 202 is located between and adjacent to the first N− drift region 204a and the second N− drift region 204b, and is doped to a lesser concentration of N− type material than the first or second N− drift regions 204a, 204b. In some embodiments, the second N− drift region 204b may be omitted, in which case the N-well region 202 is located between and adjacent to both the first N− drift region 204a and the drain D. In any case, the combination of the secondary gate structure G_{DR} and the N-well region 202 forms a secondary transistor.

The illustrated secondary gate structure G_{DR} includes a conductive layer 206, such as N+ doped polysilicon, atop a secondary insulating gate oxide (GOX2) layer 210. In some embodiments, the GOX2 layer 206 may extend beyond the vertical edges of the N-well region 202, as shown. In some embodiments, the secondary GOX2 layer 210 may differ in thickness relative to the GOX layer 110 forming part of the primary gate structure G, and thus exhibit a different local voltage threshold V_{TH}. Different oxide thicknesses (alone or in combination with different local doping levels within the body B) provide an opportunity to fine-tune the ON-resistance R_{ON} and/or the breakdown voltage BV_{DSS} of the device.

In the illustrated example, the secondary gate structure G_{DR} is surrounded by insulating spacers 210. Part of the secondary gate structure G_{DR} is coated with a dielectric 212, such as SiO₂, Si₃N₄, etc., which in turn is overlaid with an SAB layer, such as Si₃N₄, which may be co-extensive with the SAB layer 122 overlaying part of the primary gate structure G. A conductive contact 214, which may be a salicide, is formed in contact with the conductive layer 206 of the gate structure G_{DR}. A stylized electrical terminal G_{BIAS} is shown coupled to the conductive contact 214.

The electrical terminal G_{BIAS} would generally be coupled to a voltage source within an overlying superstructure (not shown). In some embodiments, the G_{BIAS} terminal may be coupled to the Gate terminal of the primary gate structure G such that both terminals are biased by a common voltage source. In other embodiments, the voltage source for the G_{BIAS} terminal may differ in value from the voltage source for the Gate terminal.

Schematically, the first N− drift region 204a may be represented as having an essentially fixed drain resistance Rd₁, the N-well 202 may be represented as having a variable drain resistance Rd₂, and the second N− drift region 204b may be represented as having an essentially fixed drain resistance Rd₃. The total drain resistance Rd is thus equal to Rd₁+Rd₂+Rd₃.

For the illustrated example embodiment, if a bias voltage G_{BIAS} of 0V is applied to the G_{BIAS} terminal, the secondary transistor is in an OFF state and the resistance Rd₂ of the N-well will have its highest value; accordingly, Rd will have its highest value. As a consequence, the device as a whole will have a high OFF state breakdown voltage. Conversely, if a bias voltage G_{BIAS} greater than the threshold voltage of the secondary transistor is applied to the G_{BIAS} terminal, the secondary transistor is in an ON state and the resistance Rd₂ of the N-well will have a lower value; accordingly, Rd will have a lower value. A reduced total drain resistance Rd through the extended drift region improves the linearity and the EVM characteristics of the device.

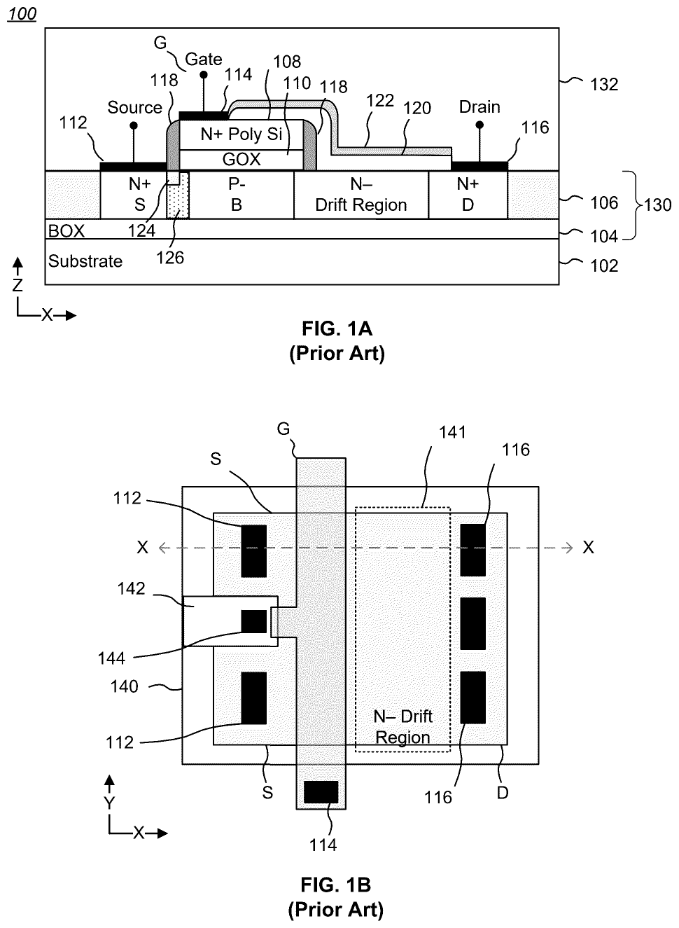

FIG. 2B is a stylized top plan view of the IC structure of FIG. 2A, excluding salicide and SAB layers. The cross-section shown in FIG. 2A is taken along line X-X in FIG. 2B. FIG. 2A is similar in many respects to FIG. 1B described above, but differs by including the secondary gate structure G_{DR} overlying an N-well region adjacent at least one of a first or second N− drift region 204a, 204b and between the N+ drain D and the P− type body B of the device.

FIG. 2C is a stylized cross-sectional view of a single SOI PEDMOS FET 250 in accordance with the present invention. Essentially, the polarity of all the semiconductor types shown in the NEDMOS FET 200 of FIG. 2A are reversed. N− type and P− type LDMOS FETs have essentially similar respective structures, minus the BOX layer 104 and the other differences noted above.

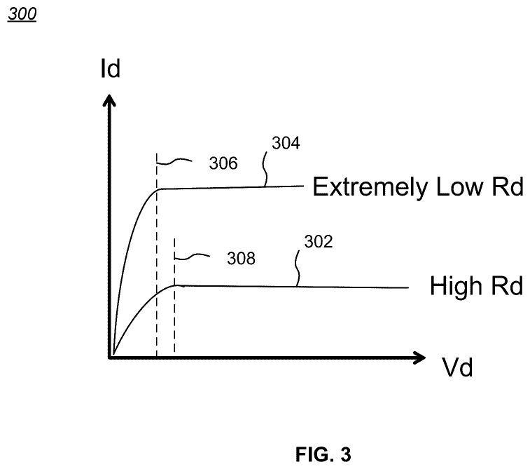

FIG. 3 is a stylized graph 300 of drain current Id versus drain voltage Vd of two different types of NEDMOS FETs. Graph line 302 shows the characteristics of a conventional NEDMOS device of the type shown in FIG. 1A. Graph line 304 shows the characteristics of an improved NEDMOS device of the type shown in FIG. 2A when the secondary gate structure G_{DR} is biased to an ON state and thus has a low Rd value. Dashed line 306 shows that the knee voltage for the novel NEDMOS device when the secondary gate structure G_{DR} is biased to an ON state is lower than the knee voltage of the conventional NEDMOS device, indicated by dashed line 308.

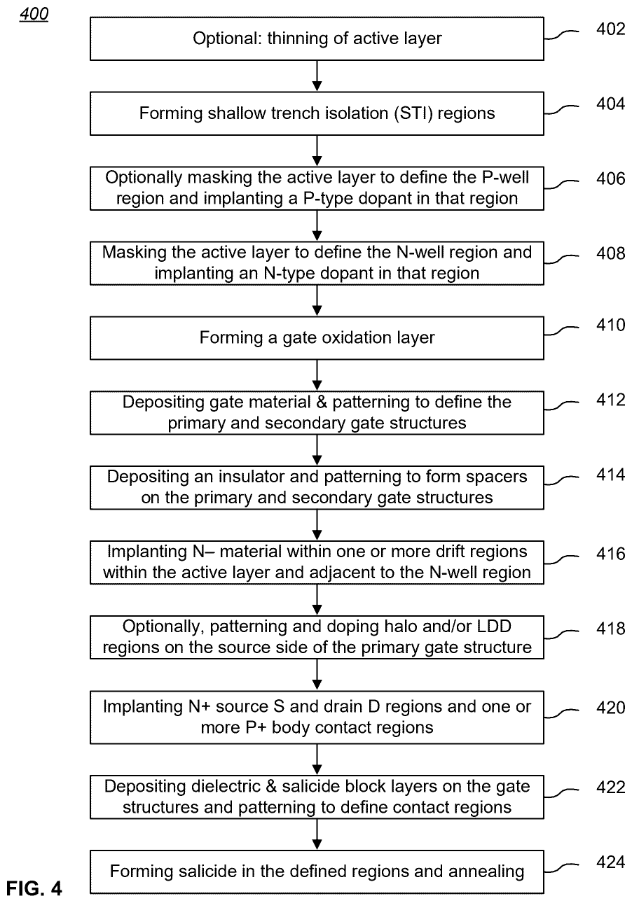

A number of different additive and/or subtractive process steps may be used to fabricate the IC architectures described in this disclosure. FIG. 4 is a process flowchart 400 showing one process for making a NEDMOS device with a secondary gate structure G_{DR} that is suitable for some contemporary IC front-end-of-line (FEOL) foundries. Note that some conventional steps, such as planarization, passivation, special implantations, annealing, formation of ohmic contacts, and formation of additional temporary or permanent structures (e.g., substrate contacts, replacement metal gate (RMG), details of masking and etching, and superstructure formation have been omitted as known to those of ordinary skill in the art. The example illustrated process includes:
(1) If needed, thinning the semiconductor active layer (e.g., Si, Ge, SiGe, SiC, or the like) formed on a substrate to a suitable thickness (Step 402).
(2) Forming shallow trench isolation (STI) regions bounding a region in which a transistor device is to be formed (Step 404).
(3) Optionally (if not using intrinsic Si for the P-well region), masking the active layer to define the P-well region and implanting a P− type dopant (e.g., boron or boron difluoride) in that region (Step 406).
(4) Masking the active layer to define the N-well region and implanting a light amount of an N− type dopant (e.g., phosphorus or arsenic) in that region (Step 408). Note that the order of the P-well and N-well doping steps may be reversed.
(5) Forming a single or multiple thickness gate oxidation layer (Step 410). If the GOX2 layer 210 is to be a different thickness than the GOX layer 110, then additional conventional steps of masking and then thinning (e.g., by etching) and/or thickening (e.g., by epitaxially growth) one or the other layer may be performed. For example, if the GOX2 layer 210 is to be thicker than the GOX layer 110, then after performing an initial oxidation to form both layers, a mask may be used to protect the GOX layer 110 where the primary gate structure G is to be formed, and to expose the GOX2 layer 210 where the secondary gate structure G_{DR} is to be formed, following by growing additional oxide in the latter region to thicken the GOX2 layer 210, for example, by thermal oxidation or chemical vapor deposition (CVD).
(6) Depositing gate material (e.g., P+ poly-Si) and patterning (e.g., masking and etching) the gate material and gate oxidation layer to define the primary gate structure G and the secondary gate structure G_{DR} (Step 412).
(7) Depositing an insulator (e.g., SiO₂) and patterning to form spacers on the primary gate structure G and the secondary gate structure G_{DR} (Step 414).
(8) Implanting N− material (e.g., by ion implantation) within one or more drift regions within the active layer and adjacent to the N-well region 202 (Step 416).
(9) Optionally, patterning halo and/or LDD regions and implanting dopant (e.g., by angled ion implantation) on the source side of the primary gate structure G (Step 418).
(10) Implanting N+ source S and drain D regions and one or more P+ body contact regions (Step 420).
(11) Depositing a dielectric layer and a salicide block layer on the gate structures and patterning to define contact regions (Step 422).
(12) Forming salicide (e.g., NiSi or Ni₂Si) in the defined contact regions and annealing (Step 424).

After formation of a basic MOSFET structure, back-end-of-line (BEOL) processes may be applied, such as fabrication of electrical contacts (pads), vias, insulating layers (dielectrics), metallization layers, and bonding sites for die-to-package connections.

As should be appreciated, other “recipes” that include additive and/or subtractive process steps may be used to fabricate EDMOS and LDMOS devices of the types described in this disclosure. Further, the fabrications steps may be performed in any feasible order.

In alternative embodiments, dummy primary and/or secondary gate structures may be formed to be later replaced by a metal gate (e.g., using an RMG process). Some embodiments may include a trap-rich layer between the BOX layer 104 and the substrate 102. A trap-rich layer mitigates parasitic surface conduction and improves device performance at high frequencies (e.g., RF frequencies). It also should be appreciated that a number of features described above may be “mixed and matched” to create further variations without departing from the scope of the invention. For example, a NEDMOS or N− type LDMOS device in accordance with the present invention may be combined with a P− type MOSFET device (e.g., a PEDMOS device or P− type LDMOS) to provide a high-voltage complementary MOS (CMOS) device pair.

Circuits and devices in accordance with the present invention may be used alone or in combination with other components, circuits, and devices. Embodiments of the present invention may be fabricated as integrated circuits (ICs), which may be encased in IC packages and/or in modules for ease of handling, manufacture, and/or improved performance. In particular, IC embodiments of this invention are often used in modules in which one or more of such ICs are combined with other circuit components or blocks (e.g., filters, amplifiers, passive components, and possibly additional ICs) into one package. The ICs and/or modules are then typically combined with other components, often on a printed circuit board, to form part of an end-product such as a cellular telephone, laptop computer, or electronic tablet, or to form a higher-level module which may be used in a wide variety of products, such as vehicles, test equipment, medical devices, etc. Through various configurations of modules and assemblies, such ICs typically enable a mode of communication, often wireless communication.

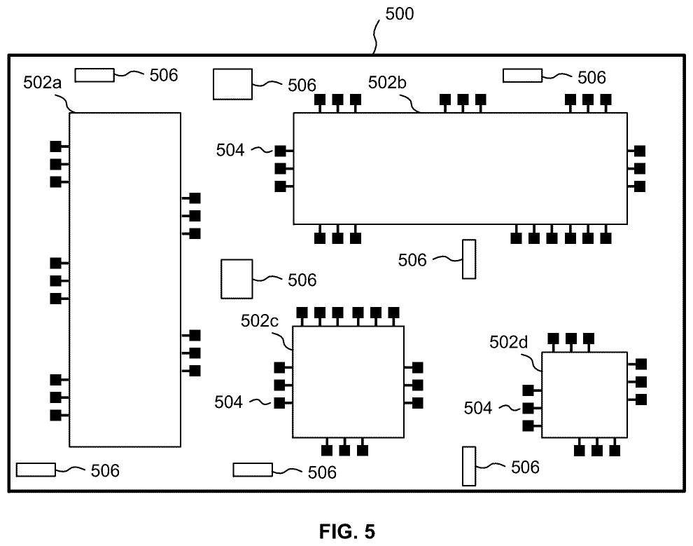

As one example of further integration of embodiments of the present invention with other components, FIG. 5 is a top plan view of a substrate 500 that may be, for example, a printed circuit board or chip module substrate (e.g., a thin-film tile). In the illustrated example, the substrate 500 includes multiple ICs 502a-502d having terminal pads 504 which would be interconnected by conductive vias and/or traces on and/or within the substrate 500 or on the opposite (back) surface of the substrate 500 (to avoid clutter, the surface conductive traces are not shown and not all terminal pads are labelled). The ICs 502a-502d may embody, for example, signal switches, active and/or passive filters, amplifiers (including one or more LNAs), and other circuitry. For example, IC 502b may incorporate one or more instances of an EDMOS or LDMOS transistor fabricated in accordance with the teachings of this disclosure.

The substrate 500 may also include one or more passive devices 506 embedded in, formed on, and/or affixed to the substrate 500. While shown as generic rectangles, the passive devices 506 may be, for example, filters, capacitors, inductors, transmission lines, resistors, antennae elements, transducers (including, for example, MEMS-based transducers, such as accelerometers, gyroscopes, microphones, pressure sensors, etc.), batteries, etc., interconnected by conductive traces on or in the substrate 500 to other passive devices 506 and/or the individual ICs 502a-502d. The front or back surface of the substrate 500 may be used as a location for the formation of other structures.

Embodiments of the present invention are useful in a wide variety of larger radio frequency (RF) circuits and systems for performing a range of functions, including (but not limited to) RF power amplifiers, RF low-noise amplifiers (LNAs), antenna beam-steering systems, charge pump devices, RF switches, etc. Such functions are useful in a variety of applications, such as radar systems (including phased array and automotive radar systems), radio systems (including cellular radio systems), and test equipment.

Radio system usage includes wireless RF systems (including base stations, relay stations, and hand-held transceivers) that use various technologies and protocols, including various types of orthogonal frequency-division multiplexing (“OFDM”), quadrature amplitude modulation (“QAM”), Code-Division Multiple Access (“CDMA”), Time-Division Multiple Access (“TDMA”), Wide Band Code Division Multiple Access (“W-CDMA”), Global System for Mobile Communications (“GSM”), Long Term Evolution (“LTE”), 5G, 6G, and WiFi (e.g., 802.11a, b, g, ac, ax, be) protocols, as well as other radio communication standards and protocols.

Another aspect of the invention includes a method of varying the resistance of a drift region of a field-effect transistor, including providing a well region within the drift region configured to have a first resistance when biased by a first bias voltage and to have a second resistance when biased by a second bias voltage.

Yet another aspect of the invention includes a method of making an integrated circuit including: fabricating a source region within an active layer on a substrate and doped to have a first semiconductor characteristic; fabricating a body region within the active layer adjacent to the source region and doped to have a second semiconductor characteristic; fabricating a primary gate structure above the body region; fabricating a first drift region within the active layer adjacent the body region and doped to have a third semiconductor characteristic; fabricating a well region within the active layer adjacent to the first drift region and doped to have a fourth semiconductor characteristic; fabricating a secondary gate structure above the well region; fabricating a second drift region within the active layer adjacent the well region and doped to have a fifth semiconductor characteristic; and fabricating a drain region within the active layer adjacent the second drift region and doped to have a sixth semiconductor characteristic.

Additional aspects of the above methods may include one or more of the following: applying a first bias voltage to the secondary gate structure to increase the resistance of the well region and applying of a second bias voltage to the secondary gate structure to decrease the resistance of the well region; wherein the first and sixth semiconductor characteristics are an N+ type and the second semiconductor characteristic is a P type; wherein the fourth semiconductor characteristic is an N type; wherein the third and fifth semiconductor characteristics are an N− type; biasing the primary gate structure and the secondary gate structure from a common voltage source; and/or fabricating the primary gate structure to include a first insulating layer having a first thickness and fabricating the secondary gate structure to include a second insulating layer having a second thickness different from the first thickness.

The term “MOSFET”, as used in this disclosure, includes any field effect transistor (FET) having an insulated gate whose voltage determines the conductivity of the transistor, and encompasses insulated gates having a metal or metal-like, insulator, and/or semiconductor structure. The terms “metal” or “metal-like” include at least one electrically conductive material (such as aluminum, copper, or other metal, or highly doped polysilicon, graphene, or other electrical conductor), “insulator” includes at least one insulating material (such as silicon oxide or other dielectric material), and “semiconductor” includes at least one semiconductor material.

As used in this disclosure, the term “radio frequency” (RF) refers to a rate of oscillation in the range of about 3 kHz to about 300 GHz. This term also includes the frequencies used in wireless communication systems. An RF frequency may be the frequency of an electromagnetic wave or of an alternating voltage or current in a circuit.

With respect to the figures referenced in this disclosure, the dimensions for the various elements are not to scale; some dimensions may be greatly exaggerated vertically and/or horizontally for clarity or emphasis. In addition, references to orientations and directions (e.g., “top”, “bottom”, “above”, “below”, “lateral”, “vertical”, “horizontal”, etc.) are relative to the example drawings, and not necessarily absolute orientations or directions.

Various embodiments of the invention can be implemented to meet a wide variety of specifications. Unless otherwise noted above, selection of suitable component values is a matter of design choice. Various embodiments of the invention may be implemented in any suitable integrated circuit (IC) technology (including but not limited to MOSFET structures), or in hybrid or discrete circuit forms. Integrated circuit embodiments may be fabricated using any suitable substrates and processes, including but not limited to standard bulk silicon, high-resistivity bulk CMOS, silicon-on-insulator (SOI), and silicon-on-sapphire (SOS). Unless otherwise noted above, embodiments of the invention may be implemented in other transistor technologies, such as BiCMOS, LDMOS, BCD, FinFET, GAAFET, and SiC-based device technologies, using 2-D, 2.5-D, and 3-D structures. However, embodiments of the invention are particularly useful when fabricated using an SOI or SOS based process, or when fabricated with processes having similar characteristics. Fabrication in CMOS using SOI or SOS processes enables circuits with low power consumption, the ability to withstand high power signals during operation due to FET stacking, good linearity, and high frequency operation (i.e., radio frequencies up to and exceeding 300 GHz). Monolithic IC implementation is particularly useful since parasitic capacitances generally can be kept low (or at a minimum, kept uniform across all units, permitting them to be compensated) by careful design.

Voltage levels may be adjusted, and/or voltage and/or logic signal polarities reversed, depending on a particular specification and/or implementing technology (e.g., NMOS, PMOS, or CMOS, and enhancement mode or depletion mode transistor devices). Component voltage, current, and power handling capabilities may be adapted as needed, for example, by adjusting device sizes, serially “stacking” components (particularly FETs) to withstand greater voltages, and/or using multiple components in parallel to handle greater currents. Additional circuit components may be added to enhance the capabilities of the disclosed circuits and/or to provide additional functionality without significantly altering the functionality of the disclosed circuits.

A number of embodiments of the invention have been described. It is to be understood that various modifications may be made without departing from the spirit and scope of the invention. For example, some of the steps described above may be order independent, and thus can be performed in an order different from that described. Further, some of the steps described above may be optional. Various activities described with respect to the methods identified above can be executed in repetitive, serial, and/or parallel fashion.

It is to be understood that the foregoing description is intended to illustrate and not to limit the scope of the invention, which is defined by the scope of the following claims, and that other embodiments are within the scope of the claims. In particular, the scope of the invention includes any and all feasible combinations of one or more of the processes, machines, manufactures, or compositions of matter set forth in the claims below. (Note that the parenthetical labels for claim elements are for ease of referring to such elements, and do not in themselves indicate a particular required ordering or enumeration of elements; further, such labels may be reused in dependent claims as references to additional elements without being regarded as starting a conflicting labeling sequence).

1. A field-effect transistor including a variable-resistance drift region.

2. The field-effect transistor of claim 1, wherein the variable-resistance drift region is controlled by a gate structure such that application of a first bias voltage to the gate structure increases the resistance of the variable-resistance drift region and application of a second bias voltage to the gate structure decreases the resistance of the variable-resistance drift region.

3. A field-effect transistor including an extended drain region configured to include a variable resistance region.

4. The field-effect transistor of claim 3, wherein a resistance of the variable resistance region is controlled by a gate structure such that application of a first bias voltage to the gate structure increases the resistance of the extended drain region and application of a second bias voltage to the gate structure decreases the resistance of the extended drain region.

5. The field-effect transistor of claim 3, wherein the field-effect transistor is an N− type extended drain metal-oxide-semiconductor transistor.

6. The field-effect transistor of claim 3, wherein the field-effect transistor is a P− type extended drain metal-oxide-semiconductor transistor.

7. The field-effect transistor of claim 3, wherein the field-effect transistor is an N− type laterally-diffused metal-oxide-semiconductor transistor.

8. The field-effect transistor of claim 3, wherein the field-effect transistor is a P− type laterally-diffused metal-oxide-semiconductor transistor.

9. An integrated circuit fabricated on a substrate and including: )
(a) a source region fabricated within an active layer on the substrate and doped to have a first semiconductor characteristic;
(b) a body region fabricated within the active layer adjacent to the source region and doped to have a second semiconductor characteristic;
(c) a primary gate structure formed above the body region;
(d) a first drift region fabricated within the active layer adjacent the body region and doped to have a third semiconductor characteristic;
(e) a well region fabricated within the active layer adjacent to the first drift region and doped to have a fourth semiconductor characteristic;
(f) a secondary gate structure formed above the well region;
(g) a second drift region fabricated within the active layer adjacent the well region and doped to have a fifth semiconductor characteristic; and
(h) a drain region fabricated within the active layer adjacent the second drift region and doped to have a sixth semiconductor characteristic.

10. The integrated circuit of claim 9, wherein application of a first bias voltage to the secondary gate structure increases the resistance of the well region and application of a second bias voltage to the secondary gate structure decreases the resistance of the well region.

11. The integrated circuit of claim 9, wherein the first and sixth semiconductor characteristics are an N+ type and the second semiconductor characteristic is a P type.

12. The integrated circuit of claim 9, wherein the fourth semiconductor characteristic is an N type.

13. The integrated circuit of claim 9, wherein the third and fifth semiconductor characteristics are an N− type.

14. The integrated circuit of claim 9, wherein the first and sixth semiconductor characteristics are a P+ type and the second semiconductor characteristic is an N type.

15. The integrated circuit of claim 9, wherein the fourth semiconductor characteristic is a P type.

16. The integrated circuit of claim 9, wherein the third and fifth semiconductor characteristics are a P− type.

17. The integrated circuit of claim 9, wherein the primary gate structure and the secondary gate structure are biased by a common voltage source.

18. The integrated circuit of claim 9, wherein the primary gate structure includes a first insulating layer having a first thickness and the secondary gate structure includes a second insulating layer having a second thickness different from the first thickness.

19. The integrated circuit of claim 9, wherein the integrated circuit is fabricated with a semiconductor-on-insulator process.

20.-34. (canceled)
